(19) United States
(12) Patent Application Publication
(10) Pub. No.: US 2025/0194380 A1
(43) Pub. Date: Jun. 12, 2025

(54) ORGANIC LIGHT-EMITTING DISPLAY APPARATUS AND METHOD OF MANUFACTURING THE SAME

(71) Applicant: Samsung Display Co., LTD., Yongin-si (KR)

(72) Inventors: Jongwoo KIM, Yongin-si (KR); Soyoung OH, Yongin-si (KR); Hyunsup YOON, Yongin-si (KR); Woosuk JUNG, Yongin-si (KR); Jaeheung HA, Yongin-si (KR)

(21) Appl. No.: 18/896,566

(22) Filed: Sep. 25, 2024

(30) Foreign Application Priority Data
Jan. 15, 2024 (KR) 10-2024-0006300

(51) Int. Cl. H10K 59/80; H10K 59/12

(52) U.S. Cl. CPC H10K 59/873; H10K 59/1201

(57) ABSTRACT

An organic light-emitting display apparatus includes a substrate, an organic light-emitting element disposed on the substrate, and an encapsulation layer covering the organic light-emitting element. The encapsulation layer includes a first inorganic encapsulation layer, a second inorganic encapsulation layer disposed on the first inorganic encapsulation layer and having a thickness in a range of about 10 Å to about 50 Å, and a third inorganic encapsulation layer disposed on the second inorganic encapsulation layer.

This application claims priority to Korean Patent Application No. 10-2024-0006300, filed on Jan. 15, 2024, and all the benefits accruing therefrom under 35 U.S.C. § 119, the content of which in its entirety is herein incorporated by reference.

### BACKGROUND

### 1. Field

One or more embodiments relate to an organic light-emitting display apparatus and a method of manufacturing the organic light-emitting display apparatus, and more particularly, to an organic light-emitting display apparatus with reduced rate of defect occurrence during manufacturing or usage and a method of manufacturing the organic light-emitting display apparatus.

### 2. Description of the Related Art

Generally, an organic light-emitting display apparatus includes a pixel circuit configured to control whether each pixel emits light and the degree of light emission, and an organic light-emitting element, which is a display element electrically connected to the pixel circuit. In addition, such an organic light-emitting display apparatus may include an encapsulation layer covering a display area to protect organic light-emitting elements from external impurities.

### SUMMARY

In a conventional organic light-emitting display apparatus, defects may occur during a manufacturing process or a life thereof may be reduced after the manufacturing.

One or more embodiments include a display apparatus with reduced defect occurrence rate during a manufacturing process or usage, and a method of manufacturing the display apparatus.

According to one or more embodiments, an organic light-emitting display apparatus includes a substrate, an organic light-emitting element disposed on the substrate, and an encapsulation layer covering the organic light-emitting element, where the encapsulation layer includes a first inorganic encapsulation layer, a second inorganic encapsulation layer disposed on the first inorganic encapsulation layer and having a thickness in a range of about 10 angstroms (Å) to about 50 Å, and a third inorganic encapsulation layer disposed on the second inorganic encapsulation layer.

In an embodiment, the second inorganic encapsulation layer may be in surface-contact with an upper surface of the first inorganic encapsulation layer, and the third inorganic encapsulation layer may be in surface-contact with an upper surface of the second inorganic encapsulation layer.

In an embodiment, a thickness of the first inorganic encapsulation layer may be greater than the thickness of the second inorganic encapsulation layer.

In an embodiment, a thickness of the third inorganic encapsulation layer may be greater than the thickness of the second inorganic encapsulation layer.

In an embodiment, the thickness of the third inorganic encapsulation layer may be greater than the thickness of the first inorganic encapsulation layer.

In an embodiment, the thickness of the first inorganic encapsulation layer may be in a range of about 2000 Å to about 5000 Å.

In an embodiment, the thickness of the third inorganic encapsulation layer may be in a range of about 4000 Å to about 10000 Å.

In an embodiment, the first inorganic encapsulation layer, the second inorganic encapsulation layer, and the third inorganic encapsulation layer may include a same material as each other.

In an embodiment, each of the first inorganic encapsulation layer, the second inorganic encapsulation layer, and the third inorganic encapsulation layer may include silicon nitride.

In an embodiment, each of the first inorganic encapsulation layer and the third inorganic encapsulation layer may be formed by chemical vapor deposition (CVD), and the second inorganic encapsulation layer may be formed by atomic layer deposition (ALD).

In an embodiment, a density of the second inorganic encapsulation layer may be greater than a density of the first inorganic encapsulation layer and a density of the third inorganic encapsulation layer.

In an embodiment, the organic light-emitting element may include a pixel electrode, an intermediate layer disposed on the pixel electrode and including an emission layer, and an opposite electrode disposed on the intermediate layer, where the organic light-emitting display apparatus may further include a capping layer that is in surface-contact with an upper surface of the opposite electrode, and the first inorganic encapsulation layer may be in surface-contact with an upper surface of the capping layer.

According to one or more embodiments, a method of manufacturing an organic light-emitting display apparatus includes forming an organic light-emitting element on a substrate, forming a first inorganic encapsulation layer to cover the organic light-emitting element by using chemical vapor deposition (CVD), forming a second inorganic encapsulation layer having a thickness in a range of about 10 Å to about 50 Å on the first inorganic encapsulation layer by using atomic layer deposition (ALD), and forming a third inorganic encapsulation layer on the second inorganic encapsulation layer by using CVD.

In an embodiment, the second inorganic encapsulation layer may be formed to be in surface-contact with an upper surface of the first inorganic encapsulation layer, and the third inorganic encapsulation layer may be formed to be in surface-contact with an upper surface of the second inorganic encapsulation layer.

In an embodiment, a thickness of the first inorganic encapsulation layer may be greater than the thickness of the second inorganic encapsulation layer.

In an embodiment, a thickness of the third inorganic encapsulation layer may be greater than the thickness of the second inorganic encapsulation layer.

In an embodiment, the thickness of the third inorganic encapsulation layer may be greater than the thickness of the first inorganic encapsulation layer.

In an embodiment, the thickness of the first inorganic encapsulation layer may be in a range of about 2000 Å to about 5000 Å.

In an embodiment, the thickness of the third inorganic encapsulation layer may be in a range of about 4000 Å to about 10000 Å.

In an embodiment, the first inorganic encapsulation layer, the second inorganic encapsulation layer, and the third inorganic encapsulation layer may include a same material as each other.

In an embodiment, each of the first inorganic encapsulation layer, the second inorganic encapsulation layer, and the third inorganic encapsulation layer may include silicon nitride.

In an embodiment, the forming the organic light-emitting element may include forming a pixel electrode, forming an intermediate layer on the pixel electrode and including an emission layer, and forming an opposite electrode on the intermediate layer, and the method may further include forming a capping layer in surface-contact with an upper surface of the opposite electrode, where the forming the first inorganic encapsulation layer may include forming the first inorganic encapsulation layer to be in surface-contact with an upper surface of the capping layer.

These and/or other features of embodiments will become apparent and more readily appreciated from the following description of various embodiments, the accompanying drawings, and claims.

### BRIEF DESCRIPTION OF THE DRAWINGS

The above and other features of certain embodiments of the disclosure will be more apparent from the following description taken in conjunction with the accompanying drawings, in which:

FIG. 1 is a schematic cross-sectional view of an organic light-emitting display apparatus according to an embodiment;

FIGS. 2 and 3 are schematic plan views of a defective organic light-emitting display apparatus;

FIG. 4 is a schematic cross-sectional view of an organic light-emitting display apparatus according to an embodiment;

FIG. 5 is a schematic cross-sectional view of an organic light-emitting display apparatus according to an embodiment; and

FIGS. 6 and 7 are schematic cross-sectional views showing a process of manufacturing the display apparatus of FIG. 4.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and any repetitive detailed description thereof may be omitted or simplified.

As used herein, when various elements such as a layer, a region, a plate, and the like are disposed “on” another element, not only the elements may be disposed “directly on” the other element, but another element may be disposed therebetween. In addition, sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

It will be understood that the terms “comprise” and/or “comprising,” or “include” and/or “including” when used in this specification, specify the presence of stated features, regions, integers, steps, operations, elements, and/or components but do not preclude the presence or addition of one or more other features, regions, integers, steps, operations, elements, components, and/or groups thereof.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be understood that when a layer, region, or element is referred to as being “connected” to another layer, region, or element, it may be “directly connected” to the other layer, region, or element or may be “indirectly connected” to the other layer, region, or element with other layer, region, or element located therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with another layer, region, or element disposed therebetween.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

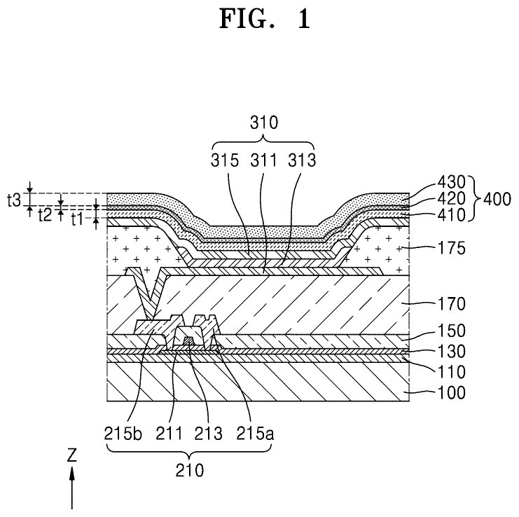

FIG. 1 is a schematic cross-sectional view of an organic light-emitting display apparatus according to an embodiment. The organic light-emitting display apparatus according to an embodiment may include a substrate 100, an organic light-emitting element 310, which is a display element disposed over the substrate 100, and an encapsulation layer 400 covering the organic light-emitting element 310.

The substrate 100 may include various flexible or bendable materials, for example, polymer resin including polyethersulphone (PES), polyacrylate, polyetherimide (PEI), polyethylene naphthalate (PEN), polyethylene terephthalate (PET), polyphenylene sulfide (PPS), polyarylate (PAR), polyimide (PI), polycarbonate (PC), or cellulose acetate propionate (CAP). The substrate 100 may have a multi-layered structure including two layers each including the polymer resin, and a barrier layer therebetween and including an inorganic material (such as silicon oxide, silicon nitride, or silicon oxynitride). However, various modifications may be made. Furthermore, in an embodiment of an organic light-emitting display apparatus where the substrate 100 is not bent, the substrate 100 may include glass or the like.

The organic light-emitting element 310 is disposed over the substrate 100. A pixel circuit may be disposed between the substrate 100 and the organic light-emitting element 310, where the pixel circuit is electrically connected to the organic light-emitting element 310 and configured to control an emission degree of the organic light-emitting element 310. For convenience of illustration, FIG. 1 shows, as an example, one thin-film transistor 210 included the pixel circuit.

In an embodiment, as shown in FIG. 1, the thin-film transistor 210 may include a semiconductor layer 211, a gate electrode 213, a source electrode 215a, and a drain electrode 215b, and the semiconductor layer 211 may include amorphous silicon, polycrystalline silicon, or an organic semiconductor material. Although FIG. 1 shows an embodiment where the thin-film transistor 210 includes the source electrode 215a and the drain electrode 215b, the disclosure is not limited thereto. In an embodiment, for example, the source electrode 215a and/or the drain electrode 215b may be a portion of a wiring. Alternatively, the thin-film transistor 210 may not have the source electrode 215a and/or the drain electrode 215b, and a source region of the semiconductor layer 211 may serve as a source electrode, or a drain region of the semiconductor layer 211 may serve as a drain electrode. In an embodiment, for example, the source region of the semiconductor layer 211 of the thin-film transistor 210 may be integrally formed with a drain region of another thin-film transistor as a single unitary indivisible part. In such an embodiment, it may be understood that a drain electrode of the other thin-film transistor is electrically connected to the source electrode of the thin-film transistor 210.

In an embodiment, to secure insulation between the semiconductor layer 211 and the gate electrode 213, a gate insulating layer 130 may be disposed between the semiconductor layer 211 and the gate electrode 213, and the gate insulating layer 130 may include an inorganic material such as silicon oxide, silicon nitride, and/or silicon oxynitride. In addition, an interlayer insulating layer 150 may be disposed on the gate electrode 213, and the interlayer insulating layer 150 may include an inorganic material such as silicon oxide, silicon nitride, and/or silicon oxynitride. The source electrode 215a and the drain electrode 215b may be disposed on the interlayer insulating layer 150. The insulating layer including the inorganic material may be formed using chemical vapor deposition (CVD) or atomic layer deposition (ALD). This is also applicable to embodiments below and modifications thereof.

A buffer layer 110 may be disposed between the thin-film transistor 210 having the above structure and the substrate 100, and the buffer layer 110 may include an inorganic material such as silicon oxide, silicon nitride, and/or silicon oxynitride. The buffer layer 110 may increase flatness of the upper surface of the substrate 100, or effectively prevent or substantially reduce impurities from a layer therebelow, e.g., the substrate 100 or the like, from penetrating into the semiconductor layer 211 of the thin-film transistor 210.

The gate electrode 213 may include a metal, for example, molybdenum or aluminum and be formed using a method such as sputtering. The gate electrode 213 may have a single-layered structure or a multi-layered structure. In an embodiment, for example, the gate electrode 213 may have a two-layered structure of Mo/Al.

The source electrode 215a and the drain electrode 215b may include a metal such as titanium or aluminum and have a single-layered structure or a multi-layered structure. In an embodiment, for example, the source electrode 215a and the drain electrode 215b may have a three-layered structure of titanium/aluminum/titanium.

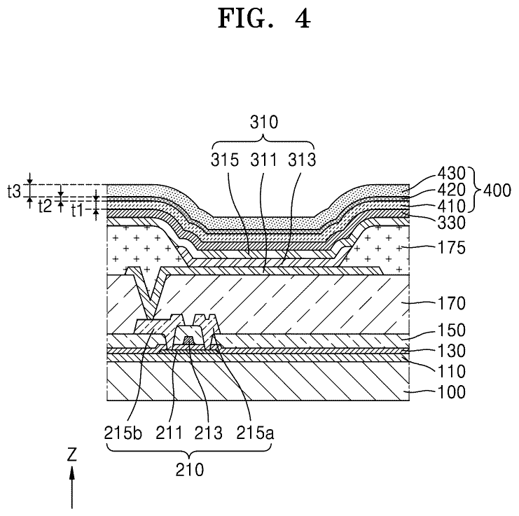

A planarization layer 170 may be disposed on the thin-film transistor 210. In an embodiment, for example, as shown in FIG. 1, the organic light-emitting element 310 is disposed on the thin-film transistor 210, and the planarization layer 170 may generally planarize the upper portion of the thin-film transistor 210. The planarization layer 170 may include an organic material, for example, acryl, benzocyclobutene (BCB), or hexamethyldisiloxane (HMDSO). FIG. 4 shows an embodiment where the planarization layer 170 is a single layer, but not being limited thereto. Alternatively, the planarization layer 170 may be a multi-layer. However, various modifications may be made.

A display element may be disposed on the planarization layer 170 in the display area of the substrate 100. The display element may be, for example, an organic light-emitting element 310 including a pixel electrode 311, an opposite electrode 315, and an intermediate layer 313, where the intermediate layer 313 is disposed between the pixel electrode 311 and the opposite electrode 315 and includes an emission layer.

In an embodiment, as shown in FIG. 1, the pixel electrode 311 is electrically connected to the thin-film transistor 210 by being in contact with one of the source electrode 215a and the drain electrode 215b through an opening defined or formed in the planarization layer 170 or the like. The pixel electrode 311 may include a light-transmissive conductive layer and a reflective layer, where the light-transmissive conductive layer includes a light-transmissive conductive oxide such as indium tin oxide (ITO), indium oxide (In₂O₃), or indium zinc oxide (IZO), and the reflective layer includes metal such as aluminum (Al) or silver (Ag). In an embodiment, for example, the pixel electrode 311 may have a three-layered structure of ITO/Ag/ITO.

A pixel-defining layer 175 may be disposed on the planarization layer 170. The pixel-defining layer 175 defines a pixel by an opening defined therethrough to correspond to each sub-pixel, that is, an opening exposing at least a central portion of the pixel electrode 311. In addition, as shown in FIG. 1, the pixel-defining layer 175 may effectively prevent arcs or the like from occurring at edges of the pixel electrode 311 by increasing a distance between the edges of the pixel electrode 311 and the opposite electrode 315 over the pixel electrode 311. The pixel-defining layer 175 may include an organic material such as polyimide or hexamethyldisiloxane (HMDSO).

The intermediate layer 313 of the organic light-emitting element 310 may include a low-molecular weight material or a polymer material. In an embodiment where the intermediate layer 313 includes a low molecular weight material, the intermediate layer 313 may have a structure in which a hole injection layer (HIL), a hole transport layer (HTL), an emission layer (EML), an electron transport layer (ETL), an electron injection layer (EIL), etc. are stacked in a single or composite configuration. The intermediate layer 313 may be formed by vacuum deposition. In an embodiment where the intermediate layer 313 includes a polymer material, the intermediate layer 313 may have a structure including an HTL and an EML. In such an embodiment, the HTL may include poly (3, 4-ethylenedioxythiophene) (PEDOT), and the EML may include a polymer material such as a polyphenylene vinylene (PPV)-based material and a polyfluorene-based material. The intermediate layer 313 may be formed by screen printing, inkjet printing, laser induced thermal imaging (LITI), or the like.

The intermediate layer 313 is not necessarily limited thereto but may have various structures. In addition, layers other than the emission layer of the intermediate layer 313 may be integrally or commonly formed over a plurality of pixel electrodes 311. The emission layer may be formed to correspond to each of the plurality of pixel electrodes 311.

The opposite electrode 315 may be arranged in the display area to cover the display area. That is, the opposite electrode 315 may be integrally or commonly formed in a plurality of organic light-emitting elements 310 to correspond to the plurality of pixel electrodes 311. The opposite electrode 315 may include a light-transmissive conductive layer including ITO, In₂O₃, or IZO, and include a semi-transmissive layer including metal such as aluminum (Al) or silver (Ag). In an embodiment, for example, the opposite electrode 315 may be a semi-transmissive layer including MgAg.

Because the organic light-emitting element 310 may be easily damaged by external moisture, oxygen, or the like, the encapsulation layer 400 may be provided to protect the organic light-emitting element 310 by covering the organic light-emitting element 310. The encapsulation layer 400 may cover the display area and extend to at least a portion of a peripheral area. The encapsulation layer 400 may include a first inorganic encapsulation layer 410, a second inorganic encapsulation layer 420 and a third inorganic encapsulation layer 430.

The first inorganic encapsulation layer 410 formed by CVD may cover the organic light-emitting element 310. Here, CVD may be plasma enhanced chemical vapor deposition (PECVD). The first inorganic encapsulation layer 410 may include silicon nitride. The first inorganic encapsulation layer 410 may be in surface-contact with the upper surface (a + direction) of the opposite electrode 315.

In an embodiment, a degree of characteristic of the first inorganic encapsulation layer 410 to prevent penetration of moisture or the like may be lower than that of the second inorganic encapsulation layer 420, which will be described below, but may alleviate a step difference caused by the shape of the lower structures. The first inorganic encapsulation layer 410 may somewhat alleviate the step difference caused by the shape of the lower structures, but due to its nature as an inorganic encapsulation layer, the first inorganic encapsulation layer 410 has a shape that roughly corresponds to the shape of the lower structures.

The second inorganic encapsulation layer 420 formed by ALD may be disposed on the first inorganic encapsulation layer 410. Specifically, the second inorganic encapsulation layer 420 may be in surface-contact with the upper surface of the first inorganic encapsulation layer 410 in the +Z direction. Here, Z direction may be a thickness direction of the organic light-emitting display apparatus or the substrate 100. Here, ALD may be plasma enhance atomic layer deposition (PEALD). The second inorganic encapsulation layer 420 may include silicon nitride. Accordingly, the first inorganic encapsulation layer 410 and the second inorganic encapsulation layer 420 may be formed using a same source, that is, a same reaction gas. In an embodiment, for example, the first inorganic encapsulation layer 410 may be formed by CVD and the second inorganic encapsulation layer 420 may be formed by ALD using SiH₄ gas and NH₃ gas. In such an embodiment, as described above, because the first inorganic encapsulation layer 410 is formed by CVD and the second inorganic encapsulation layer 420 is formed by ALD, the density of the second inorganic encapsulation layer 420 may be greater than the density of the first inorganic encapsulation layer 410.

A degree of characteristic of the second inorganic encapsulation layer 420 to prevent the penetration of moisture or the like may be higher than that of the first inorganic encapsulation layer 410. That is, the second inorganic encapsulation layer 420 has a high barrier characteristic. Accordingly, the second inorganic encapsulation layer 420 may effectively protect the organic light-emitting element 310 disposed in the lower portion (i.e., disposed therebelow) from external moisture or the like. In an embodiment, a thickness t2 of the second inorganic encapsulation layer 420 may be in a range of about 10 angstroms (Å) to about 50 Å.

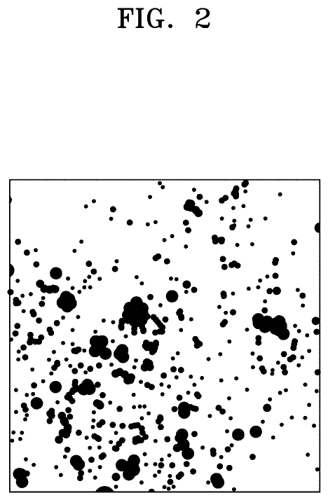

In a case where the thickness t2 of the second inorganic encapsulation layer 420 is less than about 10 Å, because the barrier characteristic of the second inorganic encapsulation layer 420 is reduced, impurities such as external moisture or the like may pass through the second inorganic encapsulation layer 420 and the first inorganic encapsulation layer 410 and reach the organic light-emitting element 310 in the lower portion thereof to cause defects. FIG. 2 is a schematic plan view of defects occurring in an organic light-emitting display apparatus having the thickness t2 of less than 10 Å and shows defects in which dark spots, such as those indicated as black, exist in the organic light-emitting display apparatus while emitting green light from the entire display surface.

In a case where the thickness t2 of the second inorganic encapsulation layer 420 exceeds about 50 Å, a probability that a crack occurs in the second inorganic encapsulation layer 420 rapidly increases. As described above, unlike the first inorganic encapsulation layer 410 formed by CVD, the second inorganic encapsulation layer 420 formed by ALD has a higher density than the density of the first inorganic encapsulation layer 410. Accordingly, because the density of the second inorganic encapsulation layer 420 is high, when the thickness t2 of the second inorganic encapsulation layer 420 exceeds 50 Å, a probability that a crack occurs in the second inorganic encapsulation layer 420 rapidly increases. Accordingly, impurities such as external moisture or the like may pass through the second inorganic encapsulation layer 420 and the first inorganic encapsulation layer 410 and reach the organic light-emitting element 310 in the lower portion thereof to cause defects.

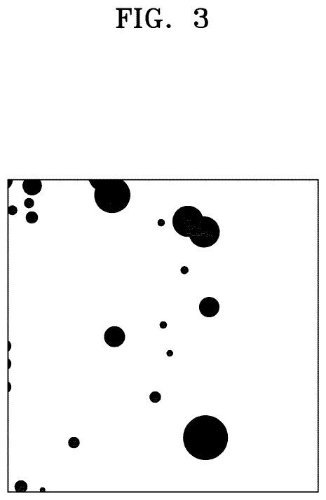

FIG. 3 is a schematic plan view of defects occurring in an organic light-emitting display apparatus having the thickness t2 exceeding 50 Å and shows defects in which dark spots, such as those indicated as black, exist in the organic light-emitting display apparatus while emitting green light from the entire display surface. For reference, in the case where the thickness t2 of the second inorganic encapsulation layer 420 exceeds 50 Å, in a foldable organic light-emitting display apparatus, cracks may occur in the second inorganic encapsulation layer 420 having a high density even due to repeated folding operations.

Referring back to FIG. 1, the third inorganic encapsulation layer 430 formed by CVD may be disposed on the second inorganic encapsulation layer 420. Specifically, the third inorganic encapsulation layer 430 may be in surface-contact with the upper surface of the second inorganic encapsulation layer 420 in the +Z direction. Here, CVD may be PECVD. The third inorganic encapsulation layer 430 may include silicon nitride. The density of the second inorganic encapsulation layer 420 may be higher than the density of the third inorganic encapsulation layer 430.

A degree of characteristic of the third inorganic encapsulation layer 430 to prevent penetration of moisture or the like may be lower than that of the second inorganic encapsulation layer 420, which is described above, but may alleviate a step difference caused by the shape of the lower structures. The third inorganic encapsulation layer 430 may somewhat alleviate the step difference caused by the shape of the lower structures, but due to its nature as an inorganic encapsulation layer, the first inorganic encapsulation layer 410 has a shape that roughly corresponds to the shape of the lower structures. In addition, the third inorganic encapsulation layer 430 may be configured to protect the second inorganic encapsulation layer 420 having a high barrier characteristic and a high density.

In an embodiment, as described above, the organic light-emitting display apparatus includes the encapsulation layer 400 including the first inorganic encapsulation layer 410, the second inorganic encapsulation layer 420, and the third inorganic encapsulation layer 430. In such an embodiment, impurities such as external moisture or the like may be effectively prevented from penetrating into the organic light-emitting element 310 and causing defects. Particularly, as described above, by ensuring that the first inorganic encapsulation layer 410, the second inorganic encapsulation layer 420, and the third inorganic encapsulation layer 430 all include a same material as each other, e.g., all include silicon nitride, these layers may be formed using a same source, that is, a same reaction gas. In an embodiment, for example, the first inorganic encapsulation layer 410 and the third inorganic encapsulation layer 430 may be formed by CVD and the second inorganic encapsulation layer 420 may be formed by ALD using SiH₄ gas and NH₃ gas. By forming the first inorganic encapsulation layer 410 and the second inorganic encapsulation layer 420 having different densities from each other using a same source, that is, a same reaction gas as described above, the process of manufacturing the organic light-emitting display apparatus may be simplified.

In such an embodiment, because the first inorganic encapsulation layer 410 is formed by CVD and the second inorganic encapsulation layer 420 is formed by ALD, the thickness t1 of the first inorganic encapsulation layer 410 may be greater than the thickness t2 of the second inorganic encapsulation layer 420. In an embodiment, the thickness t1 of the first inorganic encapsulation layer 410 may be in a range of about 2000 Å to about 5000 Å.

In such an embodiment, as described above, the degree of characteristic of the first inorganic encapsulation layer 410 to prevent penetration of moisture or the like may be lower than that of the second inorganic encapsulation layer 420, but the first inorganic encapsulation layer 410 may alleviate a step difference caused by the shape of the lower structures. The first inorganic encapsulation layer 410 may somewhat alleviate the step difference caused by the shape of the lower structures, but due to its nature as an inorganic encapsulation layer, the first inorganic encapsulation layer 410 has a shape that roughly corresponds to the shape of the lower structures. In a case where the thickness t1 of the first inorganic encapsulation layer 410 is less than about 2000 Å, the first inorganic encapsulation layer 410 may not sufficiently alleviate the step difference caused by the shape of the structures thereunder. In this case, when forming the second inorganic encapsulation layer 420 having a high density on the first inorganic encapsulation layer 410 having a thickness of less than 2000 Å, cracks or the like may occur in the second inorganic encapsulation layer 420 due to the step difference not sufficiently alleviated by the first inorganic encapsulation layer 410. Accordingly, in an embodiment, the thickness t1 of the first inorganic encapsulation layer 410 may be desired to be about 2000 Å or greater.

Due to its nature as an inorganic encapsulation layer, the first inorganic encapsulation layer 410 has a shape that roughly corresponds to the shape of the lower structures. There is no significant difference between the effect of alleviating the lower step difference by the first inorganic encapsulation layer 410 when the thickness t1 of the first inorganic encapsulation layer 410 exceeds about 5000 Å and the effect of alleviating the lower step difference by the first inorganic encapsulation layer 410 when the thickness t1 of the first inorganic encapsulation layer 410 is about 5000 Å. Accordingly, the thickness t1 of the first inorganic encapsulation layer 410 may be desired to be about 5000 Å or less.

Because the third inorganic encapsulation layer 430 is formed by CVD and the second inorganic encapsulation layer 420 is formed by ALD, the thickness t3 of the third inorganic encapsulation layer 430 may be greater than the thickness t2 of the second inorganic encapsulation layer 420. In an embodiment, the thickness t3 of the third inorganic encapsulation layer 430 may be in a range of about 4000 Å to about 10000 Å.

As described above, the degree of characteristic of the third inorganic encapsulation layer 430 to prevent penetration of moisture or the like may be lower than that of the second inorganic encapsulation layer 420, but the third inorganic encapsulation layer 430 may protect the second inorganic encapsulation layer 420 having a high density. In a case where the thickness t3 of the third inorganic encapsulation layer 430 is less than about 4000 Å, the third inorganic encapsulation layer 430 may not sufficiently protect the second inorganic encapsulation layer 420 from an externally applied impact or the like during normal use of an organic light-emitting display apparatus in the form of a smartphone, tablet computer, or the like, and thus, cracks or the like may occur in the second inorganic encapsulation layer 420 having a high density. Accordingly, in an embodiment, the thickness t3 of the third inorganic encapsulation layer 430 may be desired to be about 4000 Å or greater.

There is no significant difference between a protection effect of the second inorganic encapsulation layer 420 by the third inorganic encapsulation layer 430 when the thickness t3 of the third inorganic encapsulation layer 430 exceeds about 10000 Å and a protection effect of the second inorganic encapsulation layer 420 by the third inorganic encapsulation layer 430 when the thickness t3 of the third inorganic encapsulation layer 430 is about 10000 Å. Accordingly, in an embodiment, the thickness t3 of the third inorganic encapsulation layer 430 may be desired to be about 10000 Å or less.

As described above, the first inorganic encapsulation layer 410 and the third inorganic encapsulation layer 430 formed by a same CVD using a same source, that is, a same reaction gas perform different roles. Accordingly, in an embodiment, the thickness t3 of the third inorganic encapsulation layer 430 may be greater than the thickness t1 of the first inorganic encapsulation layer 410.

FIG. 4 is a schematic cross-sectional view of an organic light-emitting display apparatus according to an embodiment. As shown in FIG. 4, the organic light-emitting display apparatus according to an embodiment may further include a capping layer 330 that is in surface-contact with the upper surface (surface in the +Z direction) of the opposite electrode 315 of the organic light-emitting element 310. Accordingly, the first inorganic encapsulation layer 410 may be in surface-contact with the upper surface of the capping layer 330.

The capping layer 330 may have a refractive index in a range of about 1.0 to about 2.0, e.g., in a range of about 1.2 to about 1.5. The capping layer 330 may include a fluoride-based compound, for example, LiF, MgF₂, CaF₂, or ScF₃. Although FIG. 4 an embodiment where the capping layer 330 is a single layer, the disclosure is not limited thereto and the capping layer 330 may have a multi-layered structure. The thickness of the capping layer 330 may be in a range of about 200 Å to about 1000 Å. The capping layer 330 may be configured to reduce color coordinate changes depending on a viewing angle or increase light efficiency, which may be a rate at which light generated by the organic light-emitting element 310 is extracted to the outside. The capping layer 330 may be formed by vacuum deposition or spin coating.

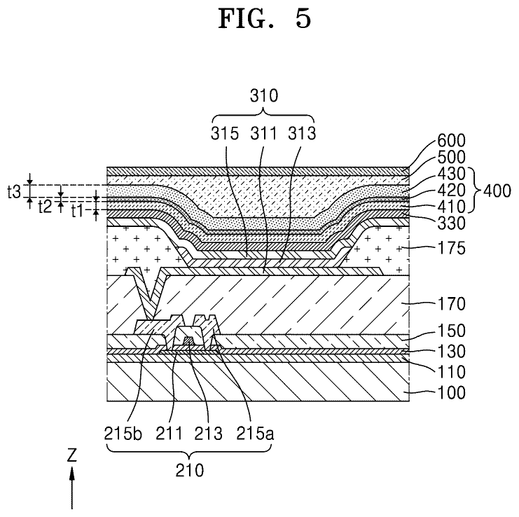

FIG. 5 is a schematic cross-sectional view of an organic light-emitting display apparatus according to an embodiment. As shown in FIG. 5, the organic light-emitting display apparatus according to an embodiment may further include an organic encapsulation layer 500 disposed on the encapsulation layer 400, and an additional inorganic encapsulation layer 600 disposed on the organic encapsulation layer 500.

The organic encapsulation layer 500 may include a polymer-based material. The polymer-based material may include an acryl-based resin (e.g., polymethyl methacrylate, polyacrylic acid, or the like), an epoxy-based resin, polyimide, and polyethylene. During the manufacturing process, monomer for forming the organic encapsulation layer 500 is disposed on the encapsulation layer 400, and then, the monomer may be irradiated with ultraviolet light or the like to become polymer. The organic encapsulation layer 500 has an approximately flat upper surface, and thus, the additional inorganic encapsulation layer 600 or the like on the organic encapsulation layer 500 may also have an approximately flat upper surface.

The additional inorganic encapsulation layer 600 may be disposed on the organic encapsulation layer 500 and may include silicon nitride. The additional inorganic encapsulation layer 600 may be formed by CVD. The additional inorganic encapsulation layer 600 may effectively prevent external moisture or the like from passing through the encapsulation layer 400 and reaching the organic light-emitting element 310.

Before the additional inorganic encapsulation layer 600 is formed, the upper surface of the organic encapsulation layer 500 may be plasma-processed. This may be understood as ashing the upper surface of the organic encapsulation layer 500. Through this surface treatment, impurities on the upper surface of the organic encapsulation layer 500 may be removed, and simultaneously, the surface of the organic encapsulation layer 500 may be reformed and changed. Through this reformation and change by the surface treatment, the surface of the organic encapsulation layer 500 is changed from hydrophobic to hydrophilic, so that when forming the additional inorganic encapsulation layer 600 afterwards, bonding force between the organic encapsulation layer 500 and the additional inorganic encapsulation layer 600 is increased. By increasing the bonding force, the additional inorganic encapsulation layer 600 may be easily formed.

In the process of surface-treating the organic encapsulation layer 500, moisture within the organic encapsulation layer 500 may be located on or near the surface of the organic encapsulation layer 500. In addition, because a process temperature is high when forming the additional inorganic encapsulation layer 600, moisture or the like within the organic encapsulation layer 500 may move to the outside (outgas) even during the process of forming the additional inorganic encapsulation layer 600. In addition, outgassing may occur from the organic encapsulation layer 500 even during the heat treatment process for reliability appraisal after manufacturing the display apparatus.

However, as described above, because the encapsulation layer 400 includes the second inorganic encapsulation layer 420 formed by ALD, having a high density, and having the thickness t2 in a range of about 10 Å to about 50 Å, even when outgassing occurs in the organic encapsulation layer 500, the second inorganic encapsulation layer 420 may be configured to effectively prevent such outgas from moving to the organic light-emitting element 310 in the lower portion.

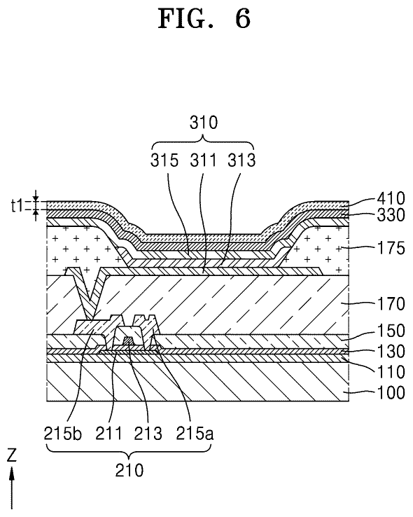

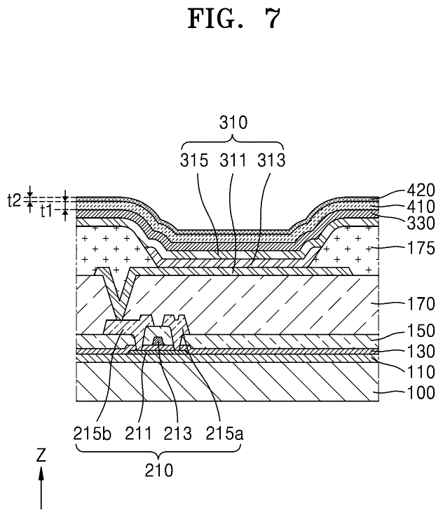

As described above, although description has been mainly made with reference to the organic light-emitting display apparatus, the disclosure is not limited thereto. That is, the manufacturing method thereof also falls within the scope of the disclosure. FIGS. 6 and 7 are schematic cross-sectional views showing a process of manufacturing the display apparatus of FIG. 4.

First, as shown in FIG. 6, the thin-film transistor 210 and the organic light-emitting element 310 electrically connected thereto are formed on the substrate 100. The specific constructions of the thin-film transistor 210 and the organic light-emitting element 310 are the same as those described above.

Subsequently, if desired, the capping layer 330 covering the organic light-emitting element 310 is formed, and then, the first inorganic encapsulation layer 410 including silicon nitride is formed to cover the organic light-emitting element 310 or formed on the capping layer 330 using CVD. The first inorganic encapsulation layer 410 may be in surface-contact with the upper surface (in the +Z direction) of the opposite electrode 315 of the organic light-emitting element 310, or in surface-contact with the upper surface (in the +Z direction) of the capping layer 330. In this case, the thickness t1 of the first inorganic encapsulation layer 410 may be in a range of about 2000 Å to about 5000 Å as described above.

The first inorganic encapsulation layer 410 is formed, and then, as shown in FIG. 7, the second inorganic encapsulation layer 420 including silicon nitride and having the thickness t2 in a range of about 10 Å to about 50 Å is formed on the first inorganic encapsulation layer 410 using ALD. The second inorganic encapsulation layer 420 may be formed to be in surface-contact with the upper surface (in the +Z direction) of the first inorganic encapsulation layer 410. In addition, the third inorganic encapsulation layer 430 including silicon nitride is formed on the second inorganic encapsulation layer 420 using CVD. The third inorganic encapsulation layer 430 may be formed to be in surface-contact with the upper surface (in the +Z direction) of the second inorganic encapsulation layer 420. In this case, the thickness t3 of the third inorganic encapsulation layer 430 may be in a range of about 4000 Å to about 10000 Å as described above.

All of the first inorganic encapsulation layer 410, the second inorganic encapsulation layer 420, and the third inorganic encapsulation layer 430 may include silicon nitride. Accordingly, the first inorganic encapsulation layer 410, the second inorganic encapsulation layer 420, and the third inorganic encapsulation layer 430 may be formed using a same source, that is, a same reaction gas. As described above, because the first inorganic encapsulation layer 410 and the third inorganic encapsulation layer 430 are formed by CVD and the second inorganic encapsulation layer 420 is formed by ALD, the density of the second inorganic encapsulation layer 420 may be greater than the density of the first inorganic encapsulation layer 410 and the density of the third inorganic encapsulation layer 430.

As described above, in the method of manufacturing the organic light-emitting display apparatus according to an embodiment, by ensuring that all of the first inorganic encapsulation layer 410, the second inorganic encapsulation layer 420, and the third inorganic encapsulation layer 430 include a same material, e.g., all include silicon nitride, these layers may be formed using a same source, that is, a same reaction gas. By forming the first inorganic encapsulation layer 410 and the second inorganic encapsulation layer 420 having different densities from each other using a same source, that is, a same reaction gas as described above, the process of manufacturing the organic light-emitting display apparatus may be simplified.

Because the first inorganic encapsulation layer 410 is formed by CVD and the second inorganic encapsulation layer 420 is formed by ALD, the thickness t1 of the first inorganic encapsulation layer 410 may be greater than the thickness t2 of the second inorganic encapsulation layer 420. In an embodiment, as described above, the thickness t1 of the first inorganic encapsulation layer 410 may be in a range of about 2000 Å to about 5000 Å.

Because the third inorganic encapsulation layer 430 is formed by CVD and the second inorganic encapsulation layer 420 is formed by ALD, the thickness t3 of the third inorganic encapsulation layer 430 may be greater than the thickness t2 of the second inorganic encapsulation layer 420. In an embodiment, as described above, the thickness t3 of the third inorganic encapsulation layer 430 may be about 4000 Å to about 10000 Å.

As described above, the first inorganic encapsulation layer 410 and the third inorganic encapsulation layer 430 formed by a same CVD using a same source, that is, a same reaction gas may perform different roles. Accordingly, in an embodiment, the thickness t3 of the third inorganic encapsulation layer 430 may be thicker than the thickness t1 of the first inorganic encapsulation layer 410.

If desired, as shown in FIG. 5, the organic encapsulation layer 500 may be formed on the encapsulation layer 400, and the additional inorganic encapsulation layer 600 may be further formed on the organic encapsulation layer 500. To form the organic encapsulation layer 500, monomer for forming the organic encapsulation layer 500 is disposed on the encapsulation layer 400, and then, the monomer may be irradiated with ultraviolet light or the like to become polymer. The additional inorganic encapsulation layer 600 may be formed to include silicon nitride by CVD. As described above, before the additional inorganic encapsulation layer 600 is formed, the upper surface of the organic encapsulation layer 500 may be plasma-processed.

According to an embodiment, a display apparatus with reduced defect occurrence rate during a manufacturing process or usage, and a method of manufacturing such a display apparatus may be implemented. However, the scope of the disclosure is not limited by this effect.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An organic light-emitting display apparatus comprising:
a substrate;
an organic light-emitting element disposed on the substrate; and
an encapsulation layer covering the organic light-emitting element,
wherein the encapsulation layer includes:
a first inorganic encapsulation layer;
a second inorganic encapsulation layer disposed on the first inorganic encapsulation layer and having a thickness in a range of about 10 Å to about 50 Å; and
a third inorganic encapsulation layer disposed on the second inorganic encapsulation layer.

2. The organic light-emitting display apparatus of claim 1, wherein
the second inorganic encapsulation layer is in surface-contact with an upper surface of the first inorganic encapsulation layer, and
the third inorganic encapsulation layer is in surface-contact with an upper surface of the second inorganic encapsulation layer.

3. The organic light-emitting display apparatus of claim 1, wherein a thickness of the first inorganic encapsulation layer is greater than the thickness of the second inorganic encapsulation layer.

4. The organic light-emitting display apparatus of claim 3, wherein a thickness of the third inorganic encapsulation layer is greater than the thickness of the second inorganic encapsulation layer.

5. The organic light-emitting display apparatus of claim 4, wherein the thickness of the third inorganic encapsulation layer is greater than the thickness of the first inorganic encapsulation layer.

6. The organic light-emitting display apparatus of claim 4, wherein the thickness of the first inorganic encapsulation layer is in a range of about 2000 Å to about 5000 Å.

7. The organic light-emitting display apparatus of claim 4, wherein the thickness of the third inorganic encapsulation layer is in a range of about 4000 Å to about 10000 Å.

8. The organic light-emitting display apparatus of claim 1, wherein the first inorganic encapsulation layer, the second inorganic encapsulation layer, and the third inorganic encapsulation layer include a same material as each other.

9. The organic light-emitting display apparatus of claim 8, wherein each of the first inorganic encapsulation layer, the second inorganic encapsulation layer, and the third inorganic encapsulation layer includes silicon nitride.

10. The organic light-emitting display apparatus of claim 1, wherein
each of the first inorganic encapsulation layer and the third inorganic encapsulation layer is formed by chemical vapor deposition (CVD), and
the second inorganic encapsulation layer is formed by atomic layer deposition (ALD).

11. The organic light-emitting display apparatus of claim 1, wherein a density of the second inorganic encapsulation layer is greater than a density of the first inorganic encapsulation layer and a density of the third inorganic encapsulation layer.

12. The organic light-emitting display apparatus of claim 1, wherein the organic light-emitting element includes:
a pixel electrode;
an intermediate layer disposed on the pixel electrode and including an emission layer; and
an opposite electrode disposed on the intermediate layer,
wherein the organic light-emitting display apparatus further comprises a capping layer which is in surface-contact with an upper surface of the opposite electrode, and
the first inorganic encapsulation layer is in surface-contact with an upper surface of the capping layer.

13. A method of manufacturing an organic light-emitting display apparatus, the method comprising:
forming an organic light-emitting element on a substrate;
forming a first inorganic encapsulation layer to cover the organic light-emitting element by using chemical vapor deposition (CVD);
forming a second inorganic encapsulation layer having a thickness in a range of about 10 Å to about 50 Å on the first inorganic encapsulation layer by using atomic layer deposition (ALD); and
forming a third inorganic encapsulation layer on the second inorganic encapsulation layer by using CVD.

14. The method of claim 13, wherein
the second inorganic encapsulation layer is formed to be in surface-contact with an upper surface of the first inorganic encapsulation layer, and
the third inorganic encapsulation layer is formed to be in surface-contact with an upper surface of the second inorganic encapsulation layer.

15. The method of claim 13, wherein a thickness of the first inorganic encapsulation layer is greater than the thickness of the second inorganic encapsulation layer.

16. The method of claim 15, wherein a thickness of the third inorganic encapsulation layer is greater than the thickness of the second inorganic encapsulation layer.

17. The method of claim 16, wherein the thickness of the third inorganic encapsulation layer is greater than the thickness of the first inorganic encapsulation layer.

18. The method of claim 16, wherein the thickness of the first inorganic encapsulation layer is in a range of about 2000 Å to about 5000 Å.

19. The method of claim 16, wherein the thickness of the third inorganic encapsulation layer is in a range of about 4000 Å to about 10000 Å.

20. The method of claim 13, wherein the first inorganic encapsulation layer, the second inorganic encapsulation layer, and the third inorganic encapsulation layer include a same material as each other.

21. The method of claim 20, wherein each of the first inorganic encapsulation layer, the second inorganic encapsulation layer, and the third inorganic encapsulation layer includes silicon nitride.

22. The method of claim 13, wherein the forming the organic light-emitting element includes:
forming a pixel electrode on the substrate;
forming an intermediate layer including an emission layer on the pixel electrode; and
forming an opposite electrode on the intermediate layer, and
wherein the method further comprises forming a capping layer in surface-contact with an upper surface of the opposite electrode,
wherein the forming the first inorganic encapsulation layer includes forming the first inorganic encapsulation layer to be in surface-contact with an upper surface of the capping layer.
